(19) United States
(12) Patent Application Publication
(10) Pub. No.: US 2023/0186459 A1
(43) Pub. Date: Jun. 15, 2023

(54) PATTERN MEASURING METHOD

(71) Applicant: TASMIT, INC., Yokohama (JP)

(72) Inventor: Shinichi NAKAZAWA, Yokohama (JP)

(21) Appl. No.: 17/925,810

(22) PCT Filed: May 6, 2021
(86) PCT No.: PCT/JP2021/017356

§ 371 Date: Nov. 16, 2022

(30) Foreign Application Priority Data
May 20, 2020 (JP) 2020-088016

(51) Int. Cl. G06T 7/00; G06T 7/33; G06T 7/60

(52) U.S. Cl. CPC G06T 7/001; G06T 7/337; G06T 7/60; G01N 23/2251

(57) ABSTRACT

The present invention relates to a method of automatically determining a measurement recipe for a feature, such as a dimension of a pattern formed on a workpiece, such as a wafer, a mask, a panel, or a substrate. This method includes: determining a type of a CAD pattern (101) and a measurement recipe based on a relative position of a measurement point (111) and the CAD pattern (101) on a coordinate system defined in design data, and an area of the CAD pattern (101); aligning a real pattern (121) on an image corresponding to the CAD pattern (101) with the CAD pattern (101); and measuring a feature of the real pattern (121) according to the determined measurement recipe.

### TECHNICAL FIELD

The present invention relates to a method of measuring a feature, such as a dimension of a pattern (critical dimension), on an image generated by an image generating apparatus, such as a scanning electron microscope, and in particular to a method of automatically determining a measurement recipe for a feature, such as a dimension of a pattern, formed on a workpiece, such as a wafer, a mask, a panel, or a substrate.

### BACKGROUND ART

Patterns formed on a workpiece, such as a wafer, a mask, a panel, or a substrate, typically have edges of various shapes, such as a straight edge and a corner edge. The patterns are formed on a surface of the workpiece according to design data (also referred to as CAD data). In CD (Critical Dimension) measurement, an image of the patterns formed on the workpiece is generated by a scanning electron microscope, and dimensions of the patterns on the image are measured.

The measurement of the dimensions of the patterns is performed at many measurement points where a pattern defect is likely to occur. These measurement points are specified on a coordinate system defined in the design data. In such dimension measurement, a measurement recipe suitable for the patterns to be measured is manually set for each measurement point.

### CITATION LIST

### Patent Literature

Patent document 1: Japanese laid-open patent publication No. 2008-235575

Patent document 2: Japanese laid-open patent publication No. 2013-92440

### SUMMARY OF INVENTION

### Technical Problem

Miniaturization of process demands to measure the pattern dimensions at a large number of measurement points in order to improve measurement accuracy. However, a conventional measuring method requires manual setting of the measurement recipe for all measurement points, and as a result, preparation for the dimension measurement takes an enormous amount of time.

Thus, the present invention provides a pattern measuring method capable of automatically determining a measurement recipe for a feature, such as a width dimension of a pattern.

### Solution to Problem

In an embodiment, there is provided a method comprising: determining a type of a CAD pattern and a measurement recipe based on a relative position of a measurement point and the CAD pattern on a coordinate system defined in design data, and an area of the CAD pattern; aligning a real pattern on an image corresponding to the CAD pattern with the CAD pattern; and measuring a feature of the real pattern according to the determined measurement recipe.

In an embodiment, the type of the CAD pattern is one selected from a plurality of types including at least an isolated pattern, a straight-line pattern, a curved-line pattern, and a termination pattern.

In an embodiment, the measurement recipe is one selected from a plurality of measurement recipes including at least measurement of a width of the real pattern on the image, measurement of a distance between real patterns on the image, and measurement of a positional shift of an edge of the real pattern on the image.

In an embodiment, the CAD pattern is determined to be the isolated pattern when the area of the CAD pattern is smaller than a predetermined area.

In an embodiment, the CAD pattern is determined to be the straight-line pattern when a first edge of the CAD pattern closest to the measurement point and a second edge located across the measurement point from the first edge do not have a vertex within a predetermined search region.

In an embodiment, the CAD pattern is determined to be the curved-line pattern when at least one of the first edge and the second edge has a vertex within the predetermined search region.

In an embodiment, the CAD pattern is determined to be the termination pattern when a length of an edge of the CAD pattern closest to the measurement point is shorter than a predetermined length and the area of the CAD pattern is larger than a predetermined area.

### Advantageous Effects of Invention

According to the present invention, the type of the CAD pattern can be determined based on the relative position of the measurement point and the CAD pattern on the design data and based on the area of the CAD pattern, and the optimum measurement recipe can be determined.

### BRIEF DESCRIPTION OF DRAWINGS

FIG. 1 is a schematic diagram showing an embodiment of an image generating system.

FIG. 2 is a schematic diagram showing an example of measurement points and CAD patterns on a coordinate system defined in design data.

FIG. 3 is a schematic diagram showing an image of real patterns on a workpiece corresponding to the CAD patterns.

FIG. 4 is a schematic diagram illustrating alignment between the CAD patterns and the corresponding real patterns on the image.

FIG. 5A is a schematic diagram showing an embodiment of measuring distances between isolated patterns.

FIG. 5B is a schematic diagram showing an embodiment of measuring the distances between the isolated patterns.

FIG. 6 is a schematic diagram illustrating an embodiment of measuring a width of a straight-line pattern.

FIG. 7 is a schematic diagram illustrating an embodiment of measuring a distance between straight-line patterns.

FIG. 8 is a schematic diagram illustrating an embodiment of measuring a width of a curved-line pattern.

FIG. 9 is a schematic diagram illustrating an embodiment of a method of determining a measuring target and a measuring direction for a curved-line pattern.

FIG. 10 is a schematic diagram illustrating an embodiment of measuring a distance between curved-line patterns.

FIG. 11 is a schematic diagram illustrating an example of measuring a positional shift of an edge of a termination pattern.

FIG. 12 is a flowchart for explaining the above-described determination of a type of the CAD pattern and a measurement recipe.

### DESCRIPTION OF EMBODIMENTS

Hereinafter, embodiments of the present invention will be described with reference to the drawings.

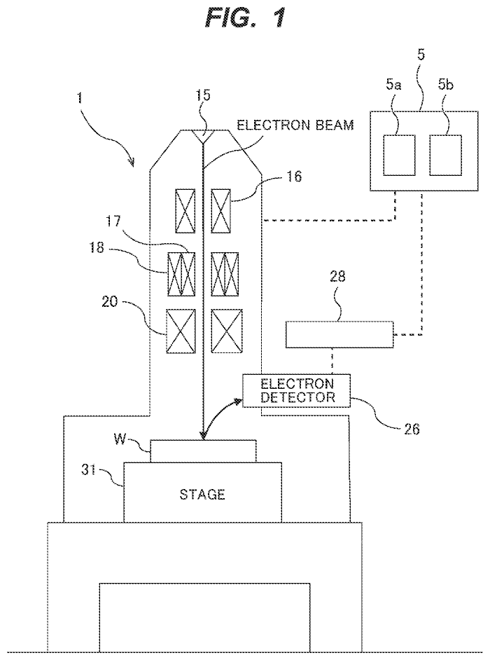

FIG. 1 is a schematic diagram showing an embodiment of an image generating system. The image generating system includes a scanning electron microscope 1 configured to generate an image of a workpiece W and an operation controller 5 configured to control operations of the scanning electron microscope 1. Examples of the workpiece W include a wafer, a mask, a panel, a substrate, etc. for use in manufacturing of semiconductor devices.

The operation controller 5 is composed of at least one computer. The operation controller 5 includes a memory 5a storing programs therein, and a processor 5b configured to perform arithmetic operations according to instructions contained in the programs. The memory 5a includes a main memory, such as a random-access memory (RAM), and an auxiliary memory, such as a hard disk drive (HDD) or a solid state drive (SSD). Examples of the processor 5b include a CPU (central processing unit) and a GPU (graphic processing unit). However, the specific configuration of the operation controller 5 is not limited to these examples.

The scanning electron microscope 1 has an electron gun 15 configured to emit an electron beam, a condenser lens 16 configured to condense the electron beam emitted from the electron gun 15, an X deflector 17 configured to deflect the electron beam in an X direction, a Y deflector 18 configured to deflect the electron beam in a Y direction, an objective lens 20 configured to focus the electron beam on the workpiece W which is an example of a specimen, and a stage 31 configured to support the workpiece W.

The electron beam emitted from the electron gun 15 is condensed by the condenser lens 16, and is then focused by the objective lens 20 onto a surface of the workpiece W, while the electron beam is deflected by the X deflector 17 and the Y deflector 18. When the workpiece W is irradiated with primary electrons of the electron beam, electrons, such as secondary electrons and backscattered electrons, are emitted from the workpiece W. The electrons emitted from the workpiece W are detected by an electron detector 26. Electron detection signals of the electron detector 26 are input to an image acquisition device 28, and are converted into an image. In this way, the scanning electron microscope 1 generates the image of the surface of the workpiece W. The image acquisition device 28 is coupled to the operation controller 5, and the image of the workpiece W is transmitted to the operation controller 5.

Hereinafter, a method of measuring a feature of a real pattern on the image generated by the scanning electron microscope 1 will be described. In the following descriptions, patterns on the workpiece W are formed based on design data (also referred to as CAD data). CAD is an abbreviation for computer-aided design. As described below, examples of the feature of the real pattern on the image include a width dimension of a real pattern, a distance between real patterns, a positional shift of an edge of a real pattern, a positional shift of an entire real pattern, an area of a real pattern (especially isolated pattern), a flattening of a real pattern (especially isolated pattern), a line-edge roughness of a real pattern (especially straight-line pattern or curved-line pattern), a curvature of a real pattern (especially curved-line pattern), and the like.

The design data of patterns formed on the workpiece W is stored in advance in the memory 5a. The design data includes design information of the patterns, such as coordinates of vertices of each pattern formed on the workpiece W, positions, shapes, and sizes of the patterns, and the number of the layer to which each pattern belongs. The operation controller 5 can read out the design data of the patterns from the memory 5a.

The design data includes design information of the patterns formed on the workpiece W. CAD patterns on the design data described below are virtual patterns defined by the design information of the patterns included in the design data, and have polygonal shapes. In the following descriptions, the patterns actually formed on the workpiece W may be referred to as real patterns.

Measurement point(s) for specifying measurement position(s) of the feature of the pattern on the image is input to the operation controller 5, and is stored in the memory 5a. In one embodiment, the measurement point(s) is point(s) at which a defect of the pattern formed on the workpiece W is likely to occur. For example, when a width dimension (CD or Critical Dimension) of a pattern at the measurement point is too long or too short, the operation controller 5 can determine that there is a defect of the pattern.

A position of each measurement point is specified by coordinates (X coordinate and Y coordinate) representing a point on a coordinate system defined in the design data. A position, a shape, and a size of each CAD pattern on the design data can also be specified by vertices of the CAD pattern on the coordinate system. Generally, a large number of measurement points are set on the coordinate system.

The operation controller 5 is configured to determine a type of CAD pattern and a measurement recipe based on an area of the CAD pattern and a relative position of the measurement point and the CAD pattern on the coordinate system defined in the design data. Types of CAD pattern include at least an isolated pattern, a straight-line pattern, a curved-line pattern, and a termination pattern.

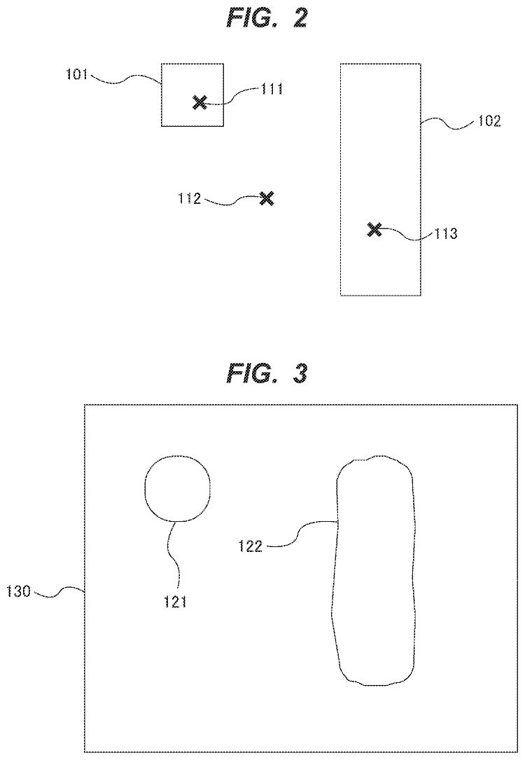

FIG. 2 is a schematic diagram showing an example of measurement points on the coordinate system defined in the design data and CAD patterns. A CAD pattern 101 is a hole pattern which is an example of the isolated pattern, and a CAD pattern 102 is the straight-line pattern. In the example shown in FIG. 2, three measurement points 111, 112, and 113 are set, and are plotted on the coordinate system.

The scanning electron microscope 1 generates an image of real patterns corresponding to the above-described CAD patterns 101 and 102. FIG. 3 is a schematic diagram showing an image 130 of real patterns 121 and 122 on the workpiece W corresponding to the CAD patterns 101 and 102. The corresponding real patterns 121 and 122 are actually formed on the workpiece W according to the above-described CAD patterns 101 and 102. The image 130 of the real patterns 121 and 122 is transmitted to the operation controller 5.

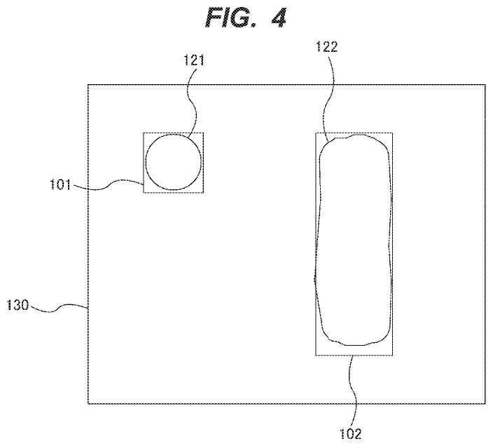

As shown in FIG. 4, the operation controller 5 aligns the CAD patterns 101 and 102 with the corresponding real patterns 121 and 122 on the image 130 of the workpiece W. The alignment is performed so as to correct a positional shift that may occur during the image generation, and allows for feature measurement at an accurate position specified by coordinates of the measurement point. A known pattern-matching technique can be used to the alignment of the real patterns 121 and 122 on the image 130 with the CAD patterns 101 and 102.

The operation controller 5 determines the type of the CAD pattern and the measurement recipe based on the relative position of the measurement point and the CAD pattern on the coordinate system and the area of the CAD pattern, and measures the feature of the real pattern on the image according to the determined measurement recipe. Hereinafter, an embodiment of a method of determining the type of CAD pattern and the measurement recipe will be described.

In the example shown in FIG. 2, the operation controller 5 first determines whether or not the given measurement points 111, 112, and 113 are located inside the CAD patterns 101 and 102 on the design data. In FIG. 2, the measurement points 111 and 113 are located inside the CAD patterns 101 and 102, respectively, and the measurement point 112 is located outside these CAD patterns 101 and 102.

The operation controller 5 calculates areas of the CAD patterns 101 and 102. When the area of the CAD pattern is smaller than a predetermined area, the operation controller 5 determines that the CAD pattern is the isolated pattern. In the example shown in FIG. 2, the area of the CAD pattern 101 is smaller than the predetermined area, and therefore the operation controller 5 determines that the CAD pattern 101 is the isolated pattern. On the other hand, the area of the CAD pattern 102 is larger than the predetermined area, and therefore the operation controller 5 determines that the CAD pattern 102 is not the isolated pattern.

The operation controller 5 measures a width of the real pattern corresponding to the CAD pattern 101 that has been determined to be the isolated pattern. Specifically, the operation controller 5 measures a width dimension (Critical Dimension) of the real pattern 121 (corresponding to the CAD pattern 101 in FIG. 2) on the image 130 shown in FIG. 3. In one embodiment, the operation controller 5 may further calculate an area and/or a flattening of the real pattern 121 as the feature of the pattern. In one embodiment, the operation controller 5 may measure a positional shift of the entire real pattern 121, i.e., an amount of shift between the real pattern 121 and the corresponding CAD pattern 101, as the feature of the pattern.

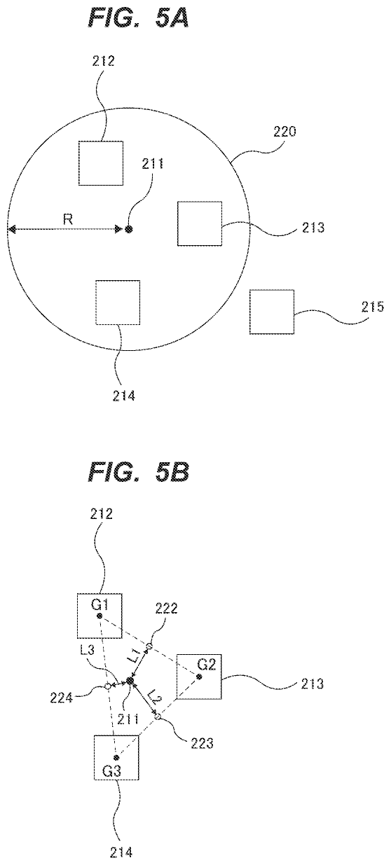

FIGS. 5A and 5B are schematic diagrams showing an embodiment of measuring distances between isolated patterns as the features. As shown in FIG. 5A, when a measurement point 211 is located outside CAD patterns 212, 213, 214, and 215, the operation controller 5 determines the CAD patterns 212, 213, and 214 located in a circular region 220 having a predetermined radius R centered on the measurement point 211. The operation controller 5 calculates areas of the CAD patterns 212, 213, and 214 located in the region 220, respectively. In the example shown in FIG. 5A, the measurement point 211 is located between the CAD patterns 212 and 213, is located between the CAD patterns 213 and 214, and is located between the CAD patterns 214 and 212.

When each of the areas of the CAD patterns 212, 213, and 214 is smaller than a predetermined area, the operation controller 5 determines that the CAD patterns 212, 213, and 214 are subjected to measuring of distances between the isolated patterns. Next, as shown in FIG. 5B, the operation controller 5 determines center-of-gravity positions G1, G2, and G3 of the CAD patterns 212, 213, and 214, and determines midpoints 222, 223, and 224 on line segments connecting the center-of-gravity position G1, G2, and G3, respectively. The operation controller 5 measures distances L1, L2, and L3 from the measurement point 211 to the midpoints 222, 223, and 224. When the measured distance is shorter than a predetermined distance, the operation controller 5 measures a distance between real patterns on the image corresponding to the CAD patterns located at both ends of the line segment including the corresponding midpoint.

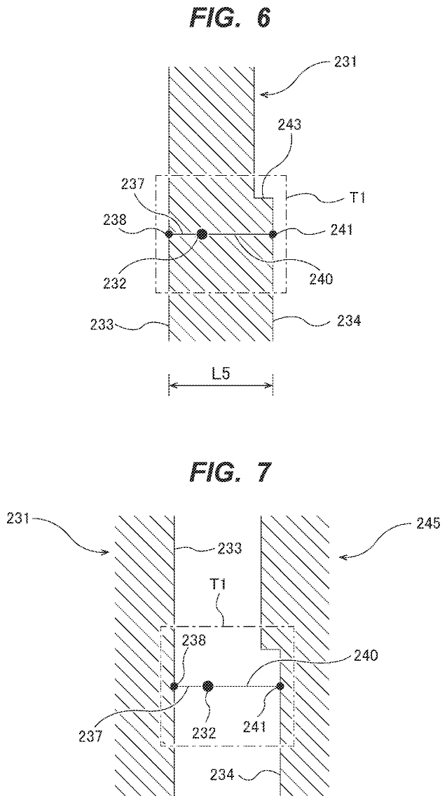

FIG. 6 is a schematic diagram illustrating an embodiment of measuring a width of the straight-line pattern as the feature. When an area of a CAD pattern 231 is larger than a predetermined area, the operation controller 5 determines that the CAD pattern 231 is not the isolated pattern. The operation controller 5 determines a first edge 233 of the CAD pattern 231 on the design data which is closest to a measurement point 232. Further, the operation controller 5 determines a second edge 234 located across the measurement point 232 from the first edge 233. The second edge 234 is parallel to the first edge 233. The measurement point 232 is located between the first edge 233 and the second edge 234.

When a distance L5 between the first edge 233 and the second edge 234 is shorter than a threshold value and the first edge 233 and the second edge 234 do not have a vertex within a predetermined search region T1, the operation controller 5 determines that the CAD pattern 231 is the straight-line pattern. The search region T1 surrounds a first intersecting point 238 of the first edge 233 and a first perpendicular line 237 which extends from the measurement point 232 and is perpendicular to the first edge 233, and further surrounds a second intersecting point 241 of the second edge 234 and a second perpendicular line 240 which extends from the measurement point 232 and is perpendicular to the second edge 234. A size of the search region T1 can be set as a parameter.

The operation controller 5 determines that the measurement point 232 is located in the CAD pattern 231, and measures a width dimension (Critical Dimension) of a real pattern on the image corresponding to the CAD pattern 231 which is the straight-line pattern. In one embodiment, the operation controller 5 may further calculate a line-edge roughness of the real pattern as the feature of the pattern. In one embodiment, the operation controller 5 may measure a positional shift of the entire real pattern, i.e., an amount of shift between the real pattern and the corresponding CAD pattern 231, as the feature of the pattern.

The edge on the design data may have a minute step 243 generated in a correcting process of the semiconductor device design. The operation controller 5 is configured to ignore a step which is smaller than a predetermined size when determining the presence or absence of a vertex of the edge. Therefore, when the edge has a minute step, the CAD pattern is determined to be the straight-line pattern.

FIG. 7 is a schematic diagram illustrating an embodiment of measuring a distance between the straight-line patterns as the feature. Operations of this embodiment, which will not be particularly described, are the same as those of the embodiment described with reference to FIG. 6, and duplicated descriptions will be omitted. In this embodiment shown in FIG. 7, the operation controller 5 determines that a measurement point 232 is located outside CAD patterns 231 and 245 on the design data and is located between the CAD patterns 231 and 245, and measures a distance between real patterns on the image corresponding to the CAD patterns 231 and 245.

FIG. 8 is a schematic diagram illustrating an embodiment of measuring a width of the curved-line pattern as the feature. The operation controller 5 determines a first edge 253 of a CAD pattern 252 on the design data which is closest to a measurement point 251. The operation controller 5 determines a second edge 255 located across the measurement point 251 from the first edge 253. The second edge 255 is parallel to the first edge 253.

The measurement point 251 is located between the first edge 253 and the second edge 255.

When a distance L6 between the first edge 253 and the second edge 255 is shorter than a threshold value and at least one of the first edge 253 and the second edge 255 has a vertex within a predetermined search region T2, the operation controller 5 determines that the CAD pattern 252 is the curved-line pattern. The search region T2 surrounds a first intersecting point 258 of the first edge 253 and a first perpendicular line 257 which extends from the measurement point 251 and is perpendicular to the first edge 253, and further surrounds a second intersecting point 261 of the second edge 255 and a second perpendicular line 260 which extends from the measurement point 251 and is perpendicular to the second edge 255. A size of the search region T2 can be set as a parameter. In the embodiment shown in FIG. 8, the first edge 253 has a vertex 264 within the search region T2, and therefore the operation controller 5 determines that the CAD pattern 252 is the curved-line pattern.

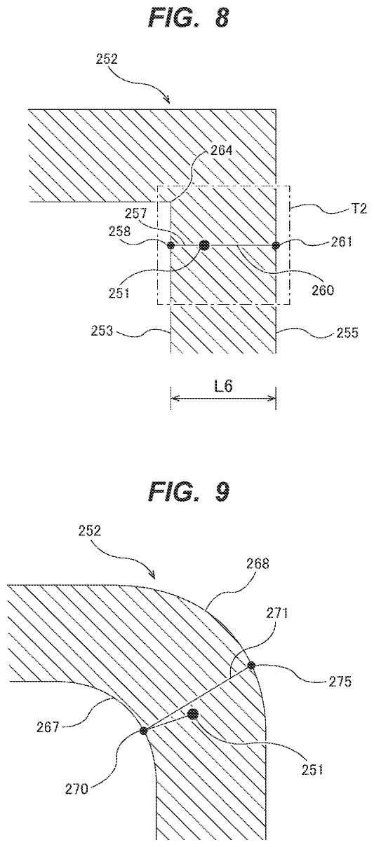

FIG. 9 is a schematic diagram illustrating an embodiment of a method of determining a measuring target and a measuring direction for the curved-line pattern. The real pattern formed on the workpiece, such as a wafer, has a corner edge having a rounded shape due to processes, such as exposure and etching. In order to imitate this shape, a rounding process is performed on the CAD pattern 252 as indicated by reference numerals 267 and 268 in FIG. 9. A circular arc, a Bezier curve, or the like is used for this rounding process.

The operation controller 5 determines a shortest point 270 at which a distance from the measurement point 251 to the curved line 267 is minimized. The operation controller 5 draws a normal line 271 of the curved line 267 from the shortest point 270 and determines an intersecting point 275 of the normal line 271 and the curved line 268 opposite to the curved line 267. The operation controller 5 measures a width of a real pattern in a direction in which the normal line 271 extends. In one embodiment, the operation controller 5 may further calculate a curvature and/or a line-edge roughness of the real pattern as the feature of the pattern.

FIG. 10 is a schematic diagram illustrating an example of measuring a distance between the curved-line patterns as the feature. Operations of this embodiment, which will not be particularly described, are the same as those of the embodiments described with reference to FIGS. 8 and 9, and duplicated descriptions will be omitted. In this embodiment shown in FIG. 10, the operation controller 5 determines that a measurement point 251 is located outside CAD patterns 252 and 278 on the design data and is located between the CAD patterns 252 and 278, and measures a distance between real patterns on the image corresponding to the CAD patterns 252 and 278.

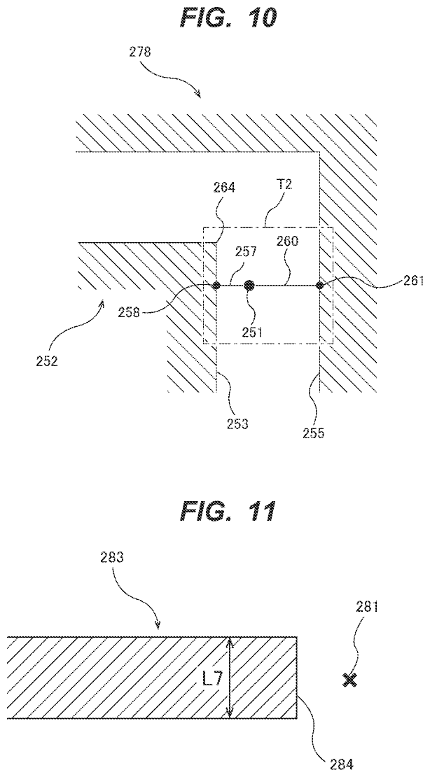

FIG. 11 is a schematic diagram illustrating an example of measuring a positional shift of an edge of the termination pattern as the feature. When a CAD pattern 283 located closest to a measurement point 281 does not correspond to any of the above types, the operation controller 5 determines whether or not the CAD pattern 283 is the termination pattern according to the following determination method. Specifically, the operation controller 5 determines an edge 284 of the CAD pattern 283 located closest to the measurement point 281. When a length L7 of the edge 284 is shorter than a predetermined length and an area of the CAD pattern 283 is larger than a predetermined area, the operation controller 5 determines that the CAD pattern 283 is the termination pattern.

The operation controller 5 detects an edge of a real pattern on the image corresponding to the edge 284 of the CAD pattern 283 which is the termination pattern, and measures a positional shift of the edge of the real pattern, i.e., a distance between the edge of the real pattern and the edge 284 of the CAD pattern 283.

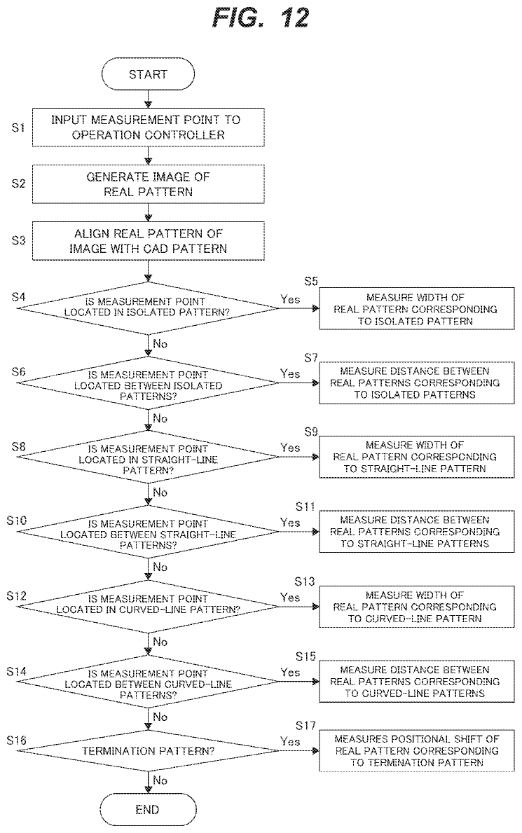

FIG. 12 is a flowchart for explaining the above-described determination of the type of the CAD pattern and the measurement recipe.

In step S1, measurement point(s) for specifying measurement position(s) of feature (e.g., dimension) of a pattern on an image is input to the operation controller 5. The measurement point(s) is located in or near a CAD pattern corresponding to a real pattern to be measured. The measurement point(s) is stored in the memory 5a.

In step S2, the operation controller 5 instructs the scanning electron microscope 1 to generate an image of the real pattern corresponding to the CAD pattern. The operation controller 5 obtains the image of the real pattern from the scanning electron microscope 1.

In step S3, the operation controller 5 aligns the real pattern on the image corresponding to the CAD pattern with the CAD pattern. A known pattern-matching technique can be used to align the real pattern on the image with the CAD pattern.

In step S4, when an area of the CAD pattern is smaller than a predetermined area, the operation controller 5 determines that the CAD pattern is an isolated pattern. Further, the operation controller 5 determines whether or not the measurement point is located in the CAD pattern. When the measurement point is located in the CAD pattern, in step S5, the operation controller 5 measures a width of the real pattern on the image corresponding to the CAD pattern which is the isolated pattern. In one embodiment, the operation controller 5 may further calculate an area and/or a flattening of the real pattern as the feature of the pattern. In one embodiment, the operation controller 5 may measure a positional shift of the entire real pattern, i.e., an amount of shift between the real pattern and the corresponding CAD pattern, as the feature of the pattern.

In step S6, the operation controller 5 determines whether or not the measurement point is located between isolated patterns. When the measurement point is located between the isolated patterns, in step S7, the operation controller 5 measures a distance between real patterns on the image corresponding to CAD patterns which are the isolated patterns.

When the CAD pattern is not an isolated pattern, the operation controller 5 determines whether or not the CAD pattern is a straight-line pattern. Specifically, in step S8, when a first edge of the CAD pattern closest to the measurement point and a second edge located across the measurement point from the first edge do not have a vertex within a predetermined search region, the operation controller 5 determines that the CAD pattern is a straight-line pattern. Further, the operation controller 5 determines whether or not the measurement point is located in the CAD pattern. When the measurement point is located in the CAD pattern, in step S9, the operation controller 5 measures a width of the real pattern on the image corresponding to the CAD pattern which is the straight-line pattern. In one embodiment, the operation controller 5 may further calculate a line-edge roughness of the real pattern as the feature of the pattern. In one embodiment, the operation controller 5 may measure a positional shift of the entire real pattern, i.e., an amount of shift between the real pattern and the corresponding CAD pattern, as the feature of the pattern.

In step S 10, the operation controller 5 determines whether or not the measurement point is located between straight-line patterns. When the measurement point is located between the straight-line patterns, in step S11, the operation controller 5 measures a distance between real patterns on the image corresponding to CAD patterns which are the straight-line patterns.

In step S12, when at least one of the above-described first edge and the above-described second edge has a vertex within a predetermined search region, the operation controller 5 determines that the CAD pattern is a curved-line pattern. Further, the operation controller 5 determines whether or not the measurement point is located in the CAD pattern. When the measurement point is located in the CAD pattern, in step S13, the operation controller 5 measures a width of a real pattern on the image corresponding to the CAD pattern which is the curved-line pattern. In one embodiment, the operation controller 5 may further calculate a curvature and/or a line-edge roughness of the real pattern as the feature of the pattern.

In step S14, the operation controller 5 determines whether or not the measurement point is located between curved-line patterns. When the measurement point is located between the curved-line patterns, in step S15, the operation controller 5 measures a distance between real patterns on the image corresponding to CAD patterns which are the curved-line patterns.

In step S16, when a length of an edge of the CAD pattern closest to the measurement point is shorter than a predetermined length and an area of the CAD pattern is larger than a predetermined area, the operation controller 5 determines that the CAD pattern is a termination pattern.

In step S17, the operation controller 5 detects an edge of a real pattern on the image corresponding to the edge of the CAD pattern which is the termination pattern, and measures a positional shift of the edge of the real pattern, i.e., a distance between the edge of the real pattern and the edge of the CAD pattern.

When the CAD pattern does not correspond to any of the isolated pattern, the straight-line pattern, the curved-line pattern, and the termination pattern, the operation controller 5 terminates the feature measurement operation.

According to the above-described embodiments, an optimum measurement recipe can be determined based on the relative position of the measurement point and the CAD pattern on the design data and based on the area of the CAD pattern.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

The present invention is applicable to a method of measuring a feature, such as a dimension of a pattern (critical dimension) on an image generated by an image generating apparatus, such as a scanning electron microscope, and in particular to a method of automatically determining a measurement recipe for a feature, such as a dimension of a pattern formed on a workpiece, such as a wafer, a mask, a panel, or a substrate.

1 scanning electron microscope

5 operation controller

15 electron gun

16 condenser lens

17 X deflector

18 Y deflector

20 objective lens

26 electron detector

31 stage

1. A method comprising:
determining whether or not a measurement point on a coordinate system defined in design data is located in a CAD pattern;
determining a type of the CAD pattern and a measurement recipe based on a relative position of the measurement point and the CAD pattern, and an area of the CAD pattern;
aligning a real pattern on an image corresponding to the CAD pattern with the CAD pattern; and
measuring a feature of the real pattern according to the determined measurement recipe.

2. The method according to claim 1, wherein the type of the CAD pattern is one selected from a plurality of types including at least an isolated pattern, a straight-line pattern, a curved.-line pattern, and a termination pattern.

3. The method according to claim 1, or wherein the measurement recipe is one selected from a plurality of measurement recipes including at least measurement of a width of the real pattern on the image, measurement of a distance between real patterns on the image, and measurement of a positional shift of an edge of the real pattern on the image.

4. The method according to claim 2, wherein the CAD pattern is determined to be the isolated pattern when the area of the CAD pattern is smaller than a predetermined area.

5. The method according to claim 2, wherein the CAD pattern is determined to be the straight-line pattern when a first edge of the CAD pattern closest to the measurement point and a second edge located across the measurement point from the first edge do not have a vertex within a predetermined search region.

6. The method according to claim 5, wherein the CAD pattern is determined to be the curved-line pattern when at least one of the first edge and the second edge has a vertex within the predetermined search region.

7. The method according to claim 2, wherein the CAD pattern is determined to be the termination pattern when a length of an edge of the CAD pattern closest to the measurement point is shorter than a predetermined length and the area of the CAD pattern is larger than a predetermined area.
